(19) United States
(12) Patent Application Publication
(10) Pub. No.: US 2026/0313874 A1
(43) Pub. Date: Oct. 8, 2026

(54) SEMICONDUCTOR DEVICE AND MANUFACTURING METHOD THEREFOR, AND ELECTRONIC DEVICE

(71) Applicant: BEIJING SUPERSTRING ACADEMY OF MEMORY TECHNOLOGY, Beijing (CN)

(72) Inventor: Jin Dai, Beijing (CN)

(73) Assignee: BEIJING SUPERSTRING ACADEMY OF MEMORY TECHNOLOGY, Beijing (CN)

(21) Appl. No.: 19/480,944

(22) PCT Filed: Apr. 18, 2024
(86) PCT No.: PCT/CN2024/088632

§ 371 Date: Nov. 3, 2025

(30) Foreign Application Priority Data
May 24, 2023 (CN) 202310586459.3

(51) Int. Cl. H10B 12/00

(52) U.S. Cl. CPC H10B 12/30; H10B 12/03

(57) ABSTRACT

A semiconductor device and a manufacturing method therefor, and an electronic device. The semiconductor device comprises: the storage unit comprises a transistor and a capacitor. The transistor comprises a channel, a first electrode, a second electrode, and a gate; the second electrode is connected to a bit line; the first electrode is connected to the capacitor; and the gate surrounds the channel and is connected to the channel by means of a gate insulating layer. The capacitor comprises a first capacitor electrode, a second capacitor electrode and a capacitor dielectric layer; the first capacitor electrode is connected to the first electrode; and the first capacitor electrode, the first electrode, the channel, and the second electrode are of integrated structures, and are formed of a same metal oxide conductive material.

### CROSS-REFERENCE TO RELATED APPLICATIONS

The present application is a U.S. National Phase Entry of International Application No. PCT/CN2024/088632 having an international filing date of Apr. 18, 2024, which claims priority to Chinese Patent Application No. 202310586459.3, filed to the CNIPA on May 24, 2023 and entitled “Semiconductor Device and Manufacturing Method Therefor, and Electronic Device”. Contents of the above-identified applications are incorporated herein by reference.

### TECHNICAL FIELD

The present disclosure relates to, but is not limited to, semiconductor technology, in particular, a semiconductor device and a manufacturing method therefore, and an electronic device.

### BACKGROUND

With the development of integrated circuit technology, the key dimensions of devices are shrinking day by day, and the types and quantities of devices contained in a single chip are increasing, so that any slight differences in process production may affect the performance of devices.

In order to reduce the cost of products as much as possible, people want to make as many device cells as possible on a limited substrate. Since Moore's Law came out, the industry has proposed various semiconductor structure designs and process optimizations to meet people's demands for current products.

### SUMMARY

The following is a summary of the subject matters described in detail in this document. This summary is not intended to limit the scope of protection of the claims.

An embodiment of the present disclosure provides a semiconductor device including: one or more memory cells stacked in a direction perpendicular to a substrate, and a bit line and a word line. A memory cell includes a transistor and a capacitor. The transistor includes a channel, a first electrode, a second electrode, and a gate, the second electrode is connected to the bit line, and the first electrode is connected to the capacitor. The gate surrounds the channel and is connected to the channel by a gate insulating layer. The capacitor includes a first capacitor electrode, a second capacitor electrode, and a capacitor dielectric layer. The first capacitor electrode is connected to the first electrode. The first capacitor electrode, the first electrode, the channel, and the second electrode are of an integrated structure and formed of a same metal oxide conductive material.

In some embodiments, a conductivity of the channel is the same as a conductivity of the first capacitor electrode, the first electrode, and the second electrode.

In some embodiments, the first capacitor electrode, the first electrode, the channel, and the second electrode are respectively different regions of the integrated structure extending in a direction parallel to the substrate.

In some embodiments, the integrated structure has a linear shape extending in the direction parallel to the substrate and perpendicular to the bit line, and an end of the integrated structure is connected to the bit line. The bit line is made of metal, alloy, or metal nitride.

In some embodiments, in the integrated structure, a region from the first capacitor electrode to the second electrode is a solid structure, and an outer side wall and an end face of the first capacitor electrode of the solid structure are surrounded by the second capacitor electrode.

In some embodiments, at least a part of regions of the integrated structure is a hollow structure. At least a region where the first capacitor electrode is located is a hollow structure, and an end of the integrated structure close to the capacitor has an opening facing the second capacitor electrode. The second capacitor electrode surrounds an outer side wall of the first capacitor electrode and penetrates into the opening, and the second capacitor electrode is connected to the outer side wall and an inner side wall of the first capacitor electrode through the capacitor dielectric layer.

In some embodiments, in the integrated structure, regions corresponding to the channel, the first electrode, and the second electrode are all solid structures.

In some embodiments, in the integrated structure, a region corresponding to the channel, the first electrode, the second electrode is a hollow structure, and the hollow structure extends from the first capacitor electrode toward the bit line to form a cup-shaped structure. The second electrode includes at least a bottom surface of the cup-shaped structure, and the bit line is connected to the bottom surface of the cup-shaped structure.

In some embodiments, each of the memory cells includes an aperture extending in a direction perpendicular to the bit line, a side wall of the aperture is an insulating layer, and a bottom of the aperture exposes the bit line of a corresponding region. A metal oxide conductive layer is deposited on the insulating layer of the aperture and on the bit line exposed at the bottom, and different regions of the metal oxide conductive layer in a direction away from the bit line are respectively the second electrode, the channel, the first electrode and the first capacitor electrode.

In some embodiments, the insulating layer of the side wall of the aperture includes different insulating layers. A region of the side wall of the aperture corresponding to the channel is the gate insulating layer, a region of the side wall of the aperture corresponding to the first capacitor electrode is the capacitor dielectric layer, and a region of the side wall of the aperture corresponding to the first electrode and the second electrode is an isolation layer.

In some embodiments, the metal oxide conductive layer is in a shape adapted to a shape of the aperture and forms a hollow cup-shaped structure, and the hollow cup-shaped structure formed by the metal oxide conductive layer is filled with an insulating filling layer.

In some embodiments, the insulating filling layer extends from the bottom of the aperture to a region of the first electrode and does not extend to a region of the first capacitor electrode. The capacitor dielectric layer is deposited on an inner side wall of the aperture not filled with the insulating filling layer, and the capacitor dielectric layer has a shape adapted to the shape of the aperture not filled with the insulating filling layer. The second capacitor electrode is filled in the aperture in which the capacitor dielectric layer is formed; the second capacitor electrode is formed in a region of an outer side wall of the aperture corresponding to the capacitor dielectric layer.

In some embodiments, the second capacitor electrode has a plate-like structure extending perpendicular to the substrate, and the first capacitor electrode extends into the plate-like structure and is connected by the capacitor dielectric layer such that shapes of the first capacitor electrode and the second capacitor electrode are complementary.

In some embodiments, the side wall of the aperture includes four surfaces, the side wall of the aperture includes an upper surface and a lower surface, and two side surfaces, and the upper surface and the lower surface are parallel to the substrate.

In some embodiments, the metal oxide conductive material is indium tin oxide.

In some embodiments, a contact between the bit line and the channel or the second electrode is an ohmic contact, and the first capacitor electrode and the channel or the first electrode are of an integrated structure.

In some embodiments, two adjacent memory cells in a same layer share one bit line, and the two adjacent memory cells are mirror-symmetrically distributed.

In some embodiments, the word line extends in a direction perpendicular to the substrate and the bit line extends in a direction parallel to the substrate.

An embodiment of the present disclosure also provides a manufacturing method for a semiconductor device, including: forming conductive layers and insulating layers disposed alternately and sequentially on a substrate; performing patterned etching to form a plurality of trenches perpendicular to the substrate, the conductive layers respectively forming patterned structures mutually stacked and sequentially circularly distributed, and each layer of the patterned structures including a bit line and a plurality of branches extending in a direction perpendicular to the bit line; filling the trenches with a dielectric layer; performing patterned etching to expose ends of the plurality of branches away from the bit line; performing wet selective etching to remove each of the branches wrapped by the dielectric layer and the insulating layers to form a trench body extending along a direction parallel to the substrate, the trench body exposing the bit line of a corresponding region; forming a continuously distributed metal oxide conductive thin film in the trench body, so that different regions of the metal oxide conductive thin film form a first capacitor electrode, a first electrode, a channel and a second electrode, the second electrode being connected to the bit line exposed; performing patterned etching to remove the dielectric layer and the insulating layers to expose the metal oxide conductive thin film in a region corresponding to the first capacitor electrode; and sequentially forming a capacitor dielectric layer and a second capacitor electrode on an outer side wall and an inner side wall of the metal oxide conductive thin film in the region corresponding to the first capacitor electrode.

In some embodiments, the method includes: forming a continuously distributed metal oxide conductive thin film on a side wall and a bottom of the trench body by an atomic layer deposition process, different regions of the metal oxide conductive thin film forming the first capacitor electrode, the first electrode, the channel and the second electrode, the second electrode being connected to the bit line at the bottom of the trench body; filling the trench body with an insulating material, the insulating material filling an entire trench body from the bottom of the trench body along the side wall; performing wet selective etching to remove only the insulating material in the region corresponding to the first capacitor electrode; and sequentially forming, in a retained trench body in the region corresponding to the first capacitor electrode, the capacitor dielectric layer and the second capacitor electrode filled in the retained trench body.

In some embodiments, after filling the trenches with the dielectric layer, the method further includes: forming a passage exposing side walls of the conductive layers in the insulating layers, the passage exposing and connecting the side walls of the conductive layers; and sequentially forming, in the passage, gate insulating layers and gates surrounding the side walls of the conductive layers. The gates are connected to form a word line, and memory cells stacked perpendicular to the substrate share one word line.

In some embodiments, after filling the trenches with the dielectric layer, the method further includes: forming a through hole extending in a vertical direction between two adjacent memory cells in a same layer, laterally etching within the through hole to expose the side walls of the conductive layers of the stacked memory cells corresponding to the two adjacent memory cells, and sequentially forming a gate insulating layer and a word line within the through hole, the word line being simultaneously connected with the two adjacent memory cells; and disconnecting the word line shared into two word lines extending along a direction perpendicular to the substrate, and forming an isolation layer between the word lines.

An embodiment of the present disclosure further an electronic device, which includes the semiconductor device described in any one of the foregoing embodiments.

In an embodiment of the present disclosure, the first capacitor electrode, the first electrode, the channel, and the second electrode are formed by the same metal oxide conductive material, so that the first capacitor electrode, the first electrode, the channel, and the second electrode are of an integrated structure, which simplifies the production process, reduces the production cost, and is easy to manufacture.

In an embodiment of the present disclosure, in the integrated structure, a region from the first capacitor electrode to the second electrode is a solid structure, so that the outer side wall and the end face of the first capacitor electrode of the solid structure are surrounded by the second capacitor electrode, thereby increasing the relative area between the second capacitor electrode and the first capacitor electrode, and improving the capacity of the capacitor.

In an embodiment of the present disclosure, at least the region where the first capacitor electrode is located is a hollow structure, and the second capacitor electrode surrounds the outer side wall of the first capacitor electrode and penetrates into the opening, thereby increasing the relative area between the second capacitor electrode and the first capacitor electrode, and improving the capacity of the capacitor.

In an embodiment of the present disclosure, the second capacitor electrode has a plate-like structure extending perpendicular to the substrate, and the first capacitor electrode extends into the plate-like structure and is connected through the capacitor dielectric layer, so that the shapes of the first capacitor electrode and the second capacitor electrode are complementary, thereby increasing the relative area between the second capacitor electrode and the first capacitor electrode, and improving the capacity of the capacitor.

Other features and advantages of the present invention will be set forth in the following specification, and moreover, partially become apparent from the specification, or are understood by implementing the present invention. The objects and advantages of the present invention can be realized and attained by the structure particularly indicated in the specification and drawings.

Other aspects may be understood upon reading and understanding the drawings and detailed description.

### BRIEF DESCRIPTION OF DRAWINGS

Accompanying drawings are used to provide further understanding of technical solutions of the present disclosure, constitute a part of the specification, and are used to explain the technical solutions of the present invention together with the embodiments of the present disclosure but not to form limitations on the technical solutions of the present disclosure.

FIG. 1 is a first schematic cross-sectional view of a semiconductor device according to an exemplary embodiment along a direction perpendicular to a substrate.

FIG. 1a is a schematic diagram obtained after insulating layers and conductive layers are formed during a manufacturing process of a semiconductor device according to an exemplary embodiment.

FIG. 1b is a schematic diagram obtained after a gate is formed during a manufacturing process of a semiconductor device according to an exemplary embodiment.

FIG. 1c is a schematic diagram obtained after a trench body is formed during a manufacturing process of a semiconductor device according to an exemplary embodiment.

FIG. 1d is a first schematic diagram obtained after a metal oxide conductive thin film is formed during a manufacturing process of a semiconductor device according to an exemplary embodiment.

FIG. 1e is a schematic diagram obtained after an integrated structure is formed during a manufacturing process of a semiconductor device according to an exemplary embodiment.

FIG. 1f is a first schematic diagram obtained after a capacitor dielectric layer is formed during a manufacturing process of a semiconductor device according to an exemplary embodiment.

FIG. 2 is a second schematic cross-sectional view of a semiconductor device according to an exemplary embodiment along a direction perpendicular to a substrate.

FIG. 2a is a second schematic diagram obtained after a metal oxide conductive thin film is formed during a manufacturing process of a semiconductor device according to an exemplary embodiment.

FIG. 2b is a schematic diagram obtained after forming a dielectric thin film during a manufacturing process of a semiconductor device according to an exemplary embodiment.

FIG. 2c is a schematic diagram obtained after an integrated structure and an insulating filling layer are formed during a manufacturing process of a semiconductor device according to an exemplary embodiment.

FIG. 2d is a second schematic diagram obtained after a capacitor dielectric layer is formed during a manufacturing process of a semiconductor device according to an exemplary embodiment.

FIG. 3 is a third schematic cross-sectional view of a semiconductor device according to an exemplary embodiment along a direction perpendicular to a substrate.

FIG. 4 is a fourth schematic cross-sectional view of a semiconductor device according to an exemplary embodiment along a direction perpendicular to a substrate.

FIG. 5a is a first schematic cross-sectional view of a gate in a semiconductor device according to an exemplary embodiment.

FIG. 5b is a second schematic cross-sectional view of a gate in a semiconductor device according to an exemplary embodiment.

FIG. 5c is a third schematic cross-sectional view of a gate in a semiconductor device according to an exemplary embodiment.

### DETAILED DESCRIPTION

The embodiments of the present disclosure will be described in detail below with reference to the accompanying drawings. The embodiments of the present disclosure and features in the embodiments may be combined with each other randomly if there is no conflict.

Unless otherwise defined, technical terms or scientific terms used in the present disclosure shall have general meanings as understood by those of ordinary skills in the art to which the present disclosure pertains.

An implementation of the present disclosure is not necessarily limited to dimensions shown in the drawings, and the shapes and sizes of the components in the drawings do not reflect actual scales. Further, the drawings schematically illustrate ideal examples, but implementations of the present disclosure are not limited to shapes or values shown in the drawings.

Ordinal numerals such as “first”, “second” and “third” in the present disclosure are provided to avoid confusion between constituent elements, but do not indicate any order, quantity or importance.

In the present disclosure, for convenience, words or expressions indicating orientation or positional relationship such as “middle”, “upper”, “lower”, “front”, “rear”, “vertical”, “horizontal”, “top”, “bottom”, “inner” and “outer” are employed to explain positional relationship of the constituent elements with reference to the accompanying drawings, they are employed for ease of description of the specification and simplification of the description only, but do not indicate or imply that the referred device or element must have a particular orientation or is constructed and operates in a particular orientation, and therefore cannot be construed as limitations on the present disclosure. The positional relationship of the constituent elements is appropriately changed according to a direction in which various constituent elements are described. Therefore, the present disclose is not limited to the words or expressions described in the present disclosure, and replacement may be appropriately made according to the situation.

In the present disclosure, terms “mount”, “couple” and “connect” should be understood broadly, unless otherwise expressly specified and defined. For example, it may be a fixed connection, a detachable connection, or an integral connection; it may be a mechanical connection or an electrical connection; it may be a direct connection, an indirect connection through a middleware, or an internal communication between two elements. For those of ordinary skills in the art, specific meanings of the above terms in the present disclosure may be understood according to actual situations.

In the present disclosure, a transistor refers to an element including at least three terminals, i.e., a gate, a drain electrode, and a source electrode. A transistor has a channel region between a drain electrode (drain electrode terminal, drain region, or drain) and a source electrode (source electrode terminal, source region, or source), and a current can flow through the drain electrode, the channel region, and the source electrode. In the present disclosure, the channel region refers to the region through which the current mainly flows.

In the present disclosure, a first electrode may be a drain electrode and a second electrode may be a source electrode, or the first electrode may be a source electrode and the second electrode may be a drain electrode. In cases that transistors with opposite polarities are used, or a current direction changes during work of a circuit, or the like, functions of the “source electrode” and the “drain electrode” may sometimes be exchanged. Therefore, in the present disclosure, the “source electrode” and the “drain electrode” are interchangeable.

In the present disclosure, “electrical connection” includes the case where the constituent elements are connected together by elements having certain electrical effects. There is no special restriction on the “elements having certain electrical effects” as long as they can transmit and receive electrical signals between connected constituent elements. Examples of the “elements having certain electrical effects” include not only electrodes and wirings, but also switching elements (such as transistors), resistors, inductors, capacitors, and other elements having various functions, etc.

In the present disclosure, “parallel” refers to approximately parallel or almost parallel, for example, a state in which the angle formed by two straight lines is −10 degrees or more and 10 degrees or less, and therefore further includes a state in which the angle is −5 degrees or more and 5 degrees or less. In addition, “perpendicular” refers to approximately perpendicular, for example, a state in which the angle formed by two straight lines is 80 degrees or more and 100 degrees or less, and therefore further includes a state in which the angle is 85 degrees or more and 95 degrees or less.

In the present disclosure, a “film” and a “layer” are interchangeable. For example, “conductive layer” may sometimes be replaced by “conductive film”. Similarly, “insulating film” may sometimes be replaced by “insulating layer”.

“A and B are arranged in a same layer” in the present disclosure means that A and B are formed simultaneously through a same patterning process. “An orthographic projection of B is within a range of an orthographic projection of A” means that a boundary of the orthographic projection of B falls within the boundary range of the orthographic projection of A, or the boundary of the orthographic projection of A overlaps with the boundary of the orthographic projection of B.

“A and B are of an integrated structure” in embodiments of the present disclosure may mean that there is no distinct boundary interface, such as distinct faultage or gaps, viewed from the microstructure. Generally, connected film layers formed by patterning on one film layer are of an integrated structure. For example, A and B form one film layer using a same material and simultaneously form a structure with a connection relationship through a same patterning process.

An embodiment of the present disclosure provides a semiconductor device including: one or more memory cells stacked in a direction perpendicular to a substrate, and a bit line and a word line. The bit line extends along a direction parallel to the substrate. The word line extends along the direction perpendicular to the substrate and penetrates the memory cells of different layers.

The memory cell includes a transistor and a capacitor.

The transistor includes a channel, a first electrode, a second electrode, and a gate. The second electrode is connected to the bit line, and the first electrode is connected to the capacitor. The gate surrounds the channel and is connected to the channel by a gate insulating layer.

The capacitor includes a first capacitor electrode, a second capacitor electrode, and a capacitor dielectric layer. The first capacitor electrode is connected to the first electrode.

The first capacitor electrode, the first electrode, the channel, and the second electrode are of an integrated structure and formed of a same metal oxide conductive material. According to a process flow of a method provided by the present application, the integrated structure includes different regions of the same metal oxide conductive material, such as different regions of a metal oxide ITO film layer, and the integrated structure includes different regions of a same metal oxide film layer.

In some embodiments, a conductivity of the channel is the same as a conductivity of the first capacitor electrode, the first electrode, and the second electrode.

In some embodiments, in the integrated structure, a region from the first capacitor electrode to the second electrode is a solid structure, and an outer side wall and an end face of the first capacitor electrode of the solid structure are surrounded by the second capacitor electrode.

In some embodiments, at least a part of regions of the integrated structure is a hollow structure.

At least a region where the first capacitor electrode is located is a hollow structure, and an end of the integrated structure close to the capacitor has an opening facing the second capacitor electrode. The second capacitor electrode surrounds an outer side wall of the first capacitor electrode and penetrates into the opening, and the second capacitor electrode is simultaneously connected to the outer side wall and an inner side wall of the first capacitor electrode through the capacitor dielectric layer.

In some embodiments, in the integrated structure, regions corresponding to the channel, the first electrode, and the second electrode are all solid structures.

In some embodiments, in the integrated structure, a region corresponding to the channel, the first electrode, and the second electrode is a hollow structure, and the hollow structure extends from the first capacitor electrode toward the bit line to form a cup-shaped structure. Different regions of a side wall of the cup-shaped structure are the first capacitor electrode, the first electrode, and the channel, the second electrode includes at least a bottom surface of the cup-shaped structure, and the bit line is connected to the bottom surface of the cup-shaped structure.

A display substrate of the present disclosure is illustrated below through some exemplary embodiments.

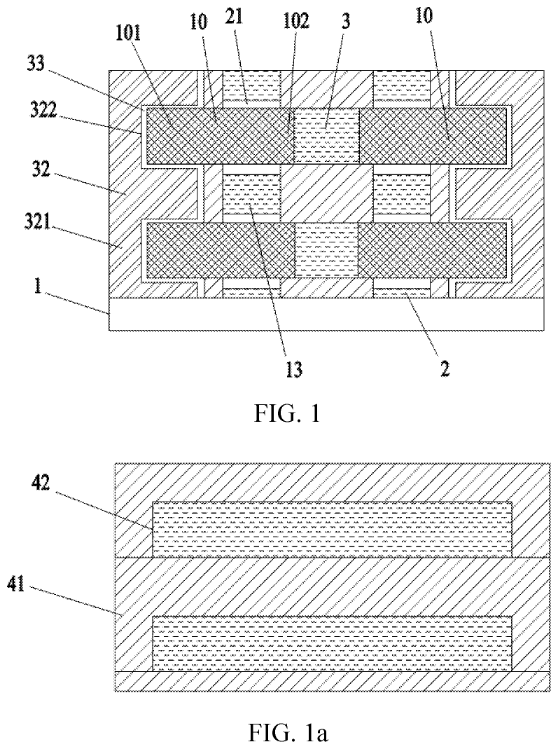

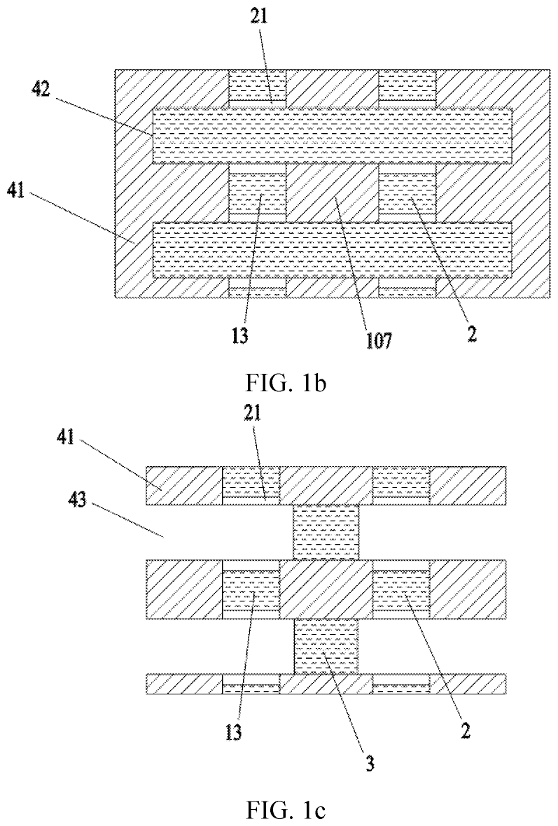

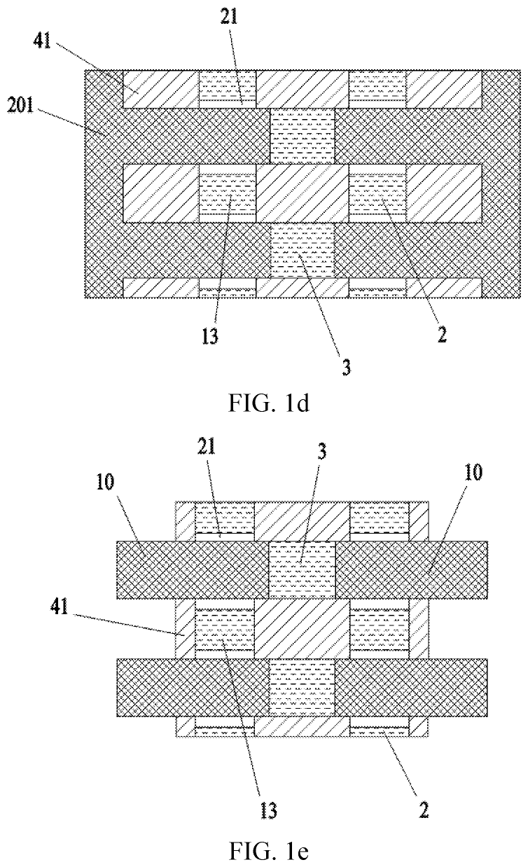

FIG. 1 is a schematic cross-sectional view of a semiconductor device according to an exemplary embodiment along a direction perpendicular to a substrate. The semiconductor device may include one or more memory cells stacked in a direction perpendicular to a substrate 1, and a word line 2 and a bit line 3 provided on the substrate 1. The word line 2 extends in the direction perpendicular to the substrate 1 and penetrates the memory cells of different layers, and the bit line 3 extends in a direction parallel to the substrate 1 and is connected to transistors in the memory cells. In FIG. 1, the word line 2 extends in the direction perpendicular to the substrate and is interconnected to individual transistors stacked, the word line 2 is distributed around the side wall of the channel in the region corresponding to the channel of the memory cell, and the bit line 3 is distributed inward and perpendicular to the paper surface.

In other embodiments, the word line extends along the direction parallel to the substrate and the bit line extends along the direction perpendicular to the substrate.

In an exemplary embodiment, as shown in FIG. 1, the memory cell may include a transistor and a capacitor. In one embodiment, a memory cell including a transistor and a capacitor forms a 1T1C structure; the transistor is connected to the bit line and the capacitor, respectively. The capacitor of the present application can be understood as a capacitive device.

In an exemplary embodiment, as shown in FIG. 1, the transistor includes a channel and a first electrode and a second electrode disposed on the channel, the first electrode and the second electrode are respectively located on opposite sides of the channel in the direction parallel to the substrate 1, and the first electrode is located on a side of the channel away from the bit line 3. The second electrode is located on a side of the channel close to the bit line 3, and is connected to the bit line 3. The channel between the first electrode and the second electrode is a horizontal channel.

In an exemplary embodiment, the second electrode, the channel, the first electrode, and the capacitor are sequentially disposed in a plane parallel to the substrate, and the arrangement direction is perpendicular to an extension direction of the bit line. The second electrode is connected to the bit line.

In an exemplary embodiment, as shown in FIG. 1, the capacitor includes a first capacitor electrode, a second capacitor electrode 32, and a capacitor dielectric layer 33, and the first capacitor electrode is located at a side of the second capacitor electrode 32 close to the bit line 3. The capacitor is electrically connected to the first electrode of the transistor.

In an exemplary embodiment, as shown in FIG. 1, the first capacitor electrode, the first electrode, the channel, and the second electrode are of an integrated structure 10, and are formed of a same metal oxide conductive material. The integrated structure 10 is a metal oxide conductive film layer.

In an exemplary embodiment, the integrated structure 10 has a linear shape extending in the direction parallel to the substrate and perpendicular to the bit line, and one end thereof is connected to the bit line 3.

In practical applications, the integrated structure can be understood as a conductive line or a linear shape, a part of the conductive line is insulated by the gate and surrounded by the gate, one end of the remaining part of the conductive line is connected to the bit line, and the other end of the remaining part of the conductive line is connected to the second capacitor electrode as the second electrode and the first capacitor electrode. The one end and the other end emphasize the connection region between the two, which in some embodiments can be understood as the end face of the line and the corresponding wire on the side, and in some embodiments can be understood as only the end face. The connection region may be a direct connection or an indirect connection.

In an exemplary embodiment, the metal oxide conductive film layer may be understood to conduct electricity when energized, such as a metal oxide having a relatively high conductivity, such as ITO, or a metal oxide having a relatively low conductivity, such as IGZO.

In some embodiments, the metal oxide conductive film layer may include at least one metal among indium, zinc, and tin.

In an exemplary embodiment, the metal oxide conductive film layer may be made of a conductor material such as ITO, IZO, or the like. The channel has the same conductivity as the first capacitor electrode, the first electrode and the second electrode, so that a same film layer is formed in one process and then patterned in one process, which can simplify the process flow. For example, a film layer is deposited by ITO, and patterned to form a conductive line, and the channel region of the conductive line of the ITO film layer is no longer modified. At the same time, ITO or similar materials have high conductivity, which can ensure that the resistance of the first electrode, the second electrode and the capacitor electrode is relatively low. At the same time, the channel can be closed by a large shut-off voltage.

The metal oxide conductive film layer is made of a conductor material (here, as compared to the case where the material is a semiconductor material before energization), so that the production process can be simplified, and the first capacitor electrode, the first electrode, the channel, and the second electrode are formed in one process using the same conductor material. In an exemplary embodiment, the metal oxide conductive film layer in the channel region may be processed to have semiconductor properties that may be a conductor or the conductive film layer under control of the gate. For example, after the ITO film layer is deposited, the ITO film layer in the channel region is modified to have semiconductor properties, and the conductivity is reduced compared with other regions. At this time, it is advantageous to turn off the transistor with a small turn-off voltage.

In an exemplary embodiment, instead of using a metal oxide having semiconductor properties (e.g. IGZO), the channel uses a metal oxide having stronger conductivity (e.g. ITO or the like), so that the positions of the first capacitor electrode and the source and drain electrodes do not need to be modified, simplifying the process flow while ensuring the electrical characteristics. The metal bit line is in direct contact with the source, drain or channel similar to ITO, so that the contact resistance is low.

In an exemplary embodiment, the metal oxide conductive film layer may be made of a material which exhibits semiconductor properties before energization, for example, IGZO. The metal oxide conductive film layer is made of a semiconductor material, so that the leakage of the semiconductor device is well suppressed when turned off and the static power consumption is low.

The metal oxide conductive film layer in regions of the first capacitor electrode, the first electrode, and the second electrode may be processed to have conductor properties, so that the conductivity of the metal oxide conductive film layer in the regions of the first capacitor electrode, the first electrode, and the second electrode is larger than the conductivity of the metal oxide conductive film layers in the region of the channel. The conductor properties of the region of the second electrode may be such that the contact between the bit line and the channel or the second electrode is an ohmic contact.

In an exemplary embodiment, the first capacitor electrode, the first electrode, the channel, and the second electrode are respectively different regions of an integrated structure extending in a direction parallel to the substrate, and the different regions of the first capacitor electrode, the first electrode, the channel, and the second electrode are sequentially disposed in a direction toward the bit line 3.

In an exemplary embodiment, one end of the integrated structure is connected to the bit line. The material of the bit line 3 is different from the material of the integrated structure, and may be a material having higher conductivity, for example, a metal or a metal nitride containing a metal, or the like, or the materials whose main component is a metal, such as a monometal or an alloy or a metal nitride having at least one of W, Ti, Al, or the like.

Alternatively, in an exemplary embodiment, the integrated structure is made of the same material as the bit line, and is formed of ITO or a material similar to ITO, so that the channel, the source, the drain and the first capacitor electrode of the entire memory cell and the bit line are of an integrated structure, and the fabrication process is simpler.

In an exemplary embodiment, as shown in FIG. 1, the transistor further includes a gate 13 and a gate insulating layer 21, and the gate 13 is connected to the channel through the gate insulating layer 21.

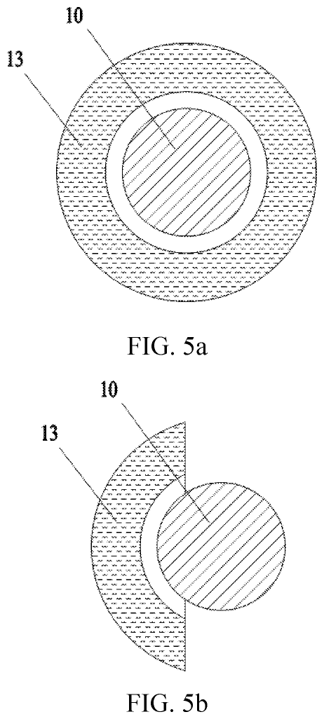

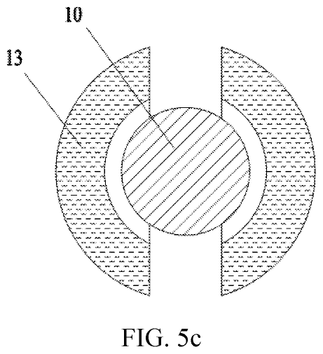

In one embodiment, the gate 13 surrounds the side wall of the integrated structure 10 in the region corresponding to the channel, as shown in FIG. 5a. Alternatively, the gate 13 surrounds the side wall of the integrated structure 10 in the region corresponding to the channel to form a “U”-shaped gate.

In one embodiment, the gate 13 is a single-side gate in the region corresponding to the channel, as shown in FIG. 5b.

In one embodiment, the gate 13 is a dule-side gate in the region corresponding to the channel, and the double gate is two independent gates surrounding two sides of the channel and connected in the peripheral region, as shown in FIG. 5c. Here, it can be understood as surrounding a part of the side wall of the channel, the surrounded region is not parallel to the substrate, for example, it can be approximately perpendicular to the side wall of the substrate, and the two side walls are opposite to each other. In this embodiment, a part of the word line may be a gate, individual gates are connected to form the word line, the word line extends along the side walls of the channels of individual stacked memory cells, the two word lines are opposite to each other, and the main surfaces of the two word lines both face the side wall of the channel.

In one embodiment, the gates 13 is a dule-side gate in the region corresponding to the channel and partially penetrates in a direction parallel to the substrate, but is physically disconnected from each other.

The embodiments of the various gates described above can be understood that, in a cross-sectional view perpendicular to the substrate, the gate may be a closed loop, or a loop with at least one opening, or have two lines extending along the direction perpendicular to the substrate.

In an exemplary embodiment, the gate insulating layer 21 is provided between the gate 13 and the region corresponding to the channel of the integrated structure 10. The gate 13 is connected to the word line 2. Here, the word line 2 is a lead common to a plurality of transistors stacked vertically, and the word line 2 is connected to the gates of individual transistors. In the stacked structure of FIG. 1, the word line is one line extending in the direction perpendicular to the substrate, and the gate 13 is a part of the word line 2. Alternatively, the word line may also be two lines, located on two sides of the channel respectively, which are approximately perpendicular to the substrate.

A first voltage may be applied to the channel of the integrated structure 10 through the gate 13, so that the channel of the integrated structure 10 is not turned on, and the transistor is turned off. A second voltage may be applied to the channel of the integrated structure 10 through the gate 13, so that the channel of the integrated structure 10 is turned on, and the transistor is turned on.

In an embodiment of the present disclosure, the first capacitor electrode, the first electrode, the channel, and the second electrode are of an integrated structure 10, and are made of a conductive metal oxide, which simplifies the production process, reduces the production cost, and is easy to manufacture.

In an exemplary embodiment, the material of the gate insulating layer 21 is not limited, which of course may be a high-K dielectric material, that is, a dielectric material having a dielectric constant K≥3.9. The high-K dielectric material may include, but is not limited to, at least one of the following: silicon oxide, aluminum oxide (Al₂O₃), hafnium oxide, and the like.

In the embodiment of the present application, the bit line can be shared to save the substrate area and increase the storage density.

For example, a column of memory cells in a same layer of memory cells is connected to a bit line, and two adjacent columns of memory cells share a bit line, which is connected to two columns of memory cells in one layer of memory cells at the same time.

For example, one column of memory cells stacked in the direction perpendicular to the substrate shares one bit line, and another column of memory cells stacked in the direction perpendicular to the substrate shares one bit line. The bit lines corresponding to the two adjacent columns of memory cells are shared, and two columns of memory cells perpendicular to the substrate can be simultaneously connected by one bit line.

In an exemplary embodiment, as shown in FIG. 1, the memory cells in a same layer form a memory cell array distributed in a row direction and a column direction, respectively, and the bit line 3 is connected to the transistors in the same column in the same layer, in particular, it may be connected to the second electrodes of the transistors. The row direction may be parallel to the substrate, the column direction may be parallel to the substrate, and the row direction and the column direction intersect. In some embodiments, the row direction and the column direction may be perpendicular.

In an exemplary embodiment, as shown in FIG. 1, transistors of adjacent memory cells in the same layer share one bit line, and two adjacent memory cells are mirror-symmetrically distributed.

In some embodiments, a metal conductive material as two side walls (side surfaces perpendicular to the substrate) of the bit line is connected to the channel or one of the source and the drain of different transistors, respectively. Since the channel or one of the source and the drain in the present application is made of a metal oxide, the contact between the bit line and the channel or the source and the drain is ohmic contact.

In an exemplary embodiment, the integrated structure may be a fully solid structure or a partially hollow structure.

In an exemplary embodiment, as shown in FIG. 1, in the integrated structure 10, a region from the first capacitor electrode to the second electrode is a solid structure, and an outer side wall and an end face of the first capacitor electrode of the solid structure are surrounded by the second capacitor electrode 32. The integrated structure 10 may extend in a direction parallel to the substrate 1. In the direction parallel to the substrate 1, the integrated structure 10 includes a first end portion 101 and a second end portion 102 disposed oppositely. The first end portion 101 is one end of the integrated structure 10 close to the second capacitor electrode 32, and the first end portion 101 is a region where the first capacitor electrode is located, and serves as an electrode plate of a capacitor. The second end portion 102 is one end of the integrated structure 10 away from the second capacitor electrode 32, and the second end portion 102 is a region where the second electrode is located, serves as an electrode of a transistor, and is connected to the bit line 3.

In an exemplary embodiment, as shown in FIG. 1, the metal oxide conductive material forming the integrated structure 10 is indium tin oxide. The contact between the bit line and the channel or the second electrode is ohmic contact, and the first capacitor electrode and the channel or the first electrode are integrated.

In an exemplary embodiment, as shown in FIG. 1, the second capacitor electrode 32 is located at a side of the integrated structure 10 away from the bit line 3, and is insulated from the integrated structure 10. The second capacitor electrode 32 includes a main body structure 321 and a recessed portion 322 provided on the main body structure 321, and the recessed portion 322 is recessed toward the inner side of the main body structure 321 along a direction parallel to the substrate 1. The recessed portion 322 is located at a side of the main body structure 321 close to the first end portion 101 of the integrated structure 10, and surrounds the outer side wall and end face of the first end 101. That is, the second capacitor electrode 32 surrounds the outer side wall and the end face of the first capacitor electrode, thereby increasing the relative area between the second capacitor electrode 32 and the first capacitor electrode, and improving the capacity of the capacitor.

In an exemplary embodiment, as shown in FIG. 1, the capacitor dielectric layer 33 is provided between the outer surface of the first end portion 101 and the inner surface of the recessed portion. The capacitor dielectric layer 33 separates the region where the first capacitor electrode of the integrated structure 10 is located from the second capacitor electrode 32.

In an exemplary embodiment, as shown in FIG. 1, in a direction perpendicular to the substrate 1, the capacitor dielectric layer 33 of the capacitors of the same column in different layers may be connected as an integrated structure. That is, the capacitors of the same column in different layers share the same capacitor dielectric layer 33.

In an exemplary embodiment, as shown in FIG. 1, in the direction perpendicular to the substrate 1, in the memory cells of the same column in different layers, the capacitor dielectric layer 33 of the capacitors has a circuitous shape along the direction perpendicular to the substrate 1. Exemplarily, the capacitor dielectric layer 33 of the capacitors has a rectangular wave shape along the direction perpendicular to the substrate 1.

In an exemplary embodiment, as shown in FIG. 1, at least two of the capacitors are stacked at intervals in the direction perpendicular to the substrate. In the direction perpendicular to the substrate, the main body structures 321 of the second capacitor electrodes 32 of adjacent capacitors are integrally connected.

Technical solutions of the embodiments will be further explained through a manufacturing process of the semiconductor device of the embodiment. A “patterning process” mentioned in the embodiments includes film layer deposition, photoresist coating, mask exposure, development, etching, photoresist stripping, and other treatments, and is a mature manufacturing process in related technologies. A “photolithography process” in the embodiments includes film layer coating, mask exposure, and development, and is a mature manufacturing process in the related technologies. Known processes such as sputtering, evaporation, chemical vapor deposition may be used for the deposition, known coating processes may be used for the coating, and known approaches may be used for etching, which are not specifically limited here. In description of the embodiments, it should be understood that a “thin film” refers to a layer of thin film made of a certain material on a base using a deposition or coating process. If the “thin film” does not need a patterning process or photolithography process during the entire manufacturing process, the “thin film” may also be called a “layer”. If the “thin film” needs a patterning process or photolithography process during the entire manufacturing process, it is called a “thin film” before the patterning process and a “layer” after the patterning process. The “layer” after the patterning process or photolithography process contains at least one “pattern”.

In the present embodiment, each layer includes a plurality of memory cells, but the embodiment of the present disclosure is not limited thereto, and each layer may include one memory cell.

In an exemplary embodiment, the semiconductor device may be the semiconductor device described in any one of above embodiments, and the manufacturing process of the semiconductor device may include following steps.
Step 101: forming patterned insulating layers and conductive layers.

Forming the insulating layers and the conductive layers includes forming conductive layers 42 and insulating layers 41 disposed alternately and sequentially on a substrate 1, and performing patterned etching through a mask to form a plurality of trenches perpendicular to the substrate. The insulating layers 41 respectively form first patterned structures mutually stacked and sequentially circularly distributed, the conductive layers 42 respectively form second patterned structures mutually stacked and sequentially circularly distributed, and each layer of the second patterned structure includes a bit line and a plurality of branches extending in a direction perpendicular to the bit line, as shown in FIG. 1a.

The conductive layer is used to form the bit line and a sacrificial layer of the transistor, and the conductive layer may be a metal, a metal nitride, or the like. Alternatively, the conductive layer may be more than one layer, one of which is a wire of the main body structure, and the other protective layer or isolation layer functions to prevent the metal from being oxidized.

In an exemplary embodiment, the insulating layer and the conductive layer may be deposited by a chemical vapor deposition method.

In an exemplary embodiment, the substrate may be a semiconductor substrate, such as a silicon substrate. Alternatively, it may be any substrate that serves as a support, not only a base, but may be a substrate formed of peripheral circuits or the like on the base.

In an exemplary embodiment, the insulating layer functions as an isolation between devices, and may be a low-K dielectric layer, that is, a dielectric layer having a dielectric constant K<3.9, including but not limited to silicon oxide, such as silicon dioxide (SiO₂) and the like.
Step 102: forming a gate and a word line.

Forming the gate includes: first filling the trenches with a dielectric layer on the basis of the substrate 1 on which the aforementioned patterns are formed. The dielectric layer may be made of the same material as the insulating layer between the conductive layers, such as silicon oxide, or it may be made of a different material. If the materials are the same, the subsequent etching process for exposing the capacitor electrode and forming the gate electrode is relatively simple.

Subsequently, a passage exposing the side walls of the conductive layers 42 is formed in the insulating layers 41, and the passage exposes and connects the side walls of the conductive layers 42. Subsequently, gate insulating layers 21 and gates 13 surrounding the side walls of the conductive layers 42 are sequentially formed in the passage, individual gates 13 are connected to form the word line 2, and one word line 2 simultaneously connects individual memory cells stacked perpendicular to the substrate, as shown in FIG. 1b.

Exemplarily, the gates 13 in two adjacent memory cells in the same layer may be formed by the same preparation process. Specifically, a through hole extending in a vertical direction is first formed between two adjacent memory cells in the same layer, and lateral etching is performed within the through hole to expose side walls of the conductive layers 42 of stacked memory cells corresponding to the two adjacent memory cells. Subsequently, the gate insulating layer 21 and word line are sequentially formed in the through hole, and the word line is simultaneously connected to two adjacent memory cells in the memory cell array of the same layer. Finally, the shared word line is disconnected into two mutually insulated word lines extending along the direction perpendicular to the substrate, and a first isolation layer 107 is formed between the word lines, as shown in FIG. 1b. The isolation layer may also be silicon oxide, which is the same material as the insulating layer.
Step 103: forming a trench body.

Forming the trench body includes: on the basis of the substrate 1 on which the aforementioned patterns are formed, first performing patterned etching to expose ends of the plurality of branches of the conductive layer 42 away from the bit line; subsequently, performing wet selective etching to remove each of the branches wrapped by the dielectric layer and the insulating layer to form a trench body 43 extending along the direction parallel to the substrate. The trench body 43 exposes the inner walls of the bit line 3, the gate insulating layer 21, and the insulating layer 41 in the corresponding regions, as shown in FIG. 1c.
Step 104: forming a metal oxide conductive thin film.

Forming the metal oxide conductive thin film includes: on the basis of the substrate 1 on which the aforementioned patterns are formed, forming a continuously distributed metal oxide conductive thin film 201 in the trench body by an atomic layer deposition process, so that different regions of the metal oxide conductive thin film 201 form a first capacitor electrode, a first electrode, a channel, and a second electrode. The second electrode is connected to the exposed bit line 3, and the metal oxide conductive thin film 201 in the trench body has a solid structure, as shown in FIG. 1d.

In an exemplary embodiment, the metal oxide conductive thin film includes, but is not limited to, at least one of Indium Gallium Zinc Oxide (IGZO), Indium Tin Oxide (ITO), and Indium Zinc Oxide (IZO).
Step 105: forming an integrated structure.

Forming the integrated structure includes on the basis of the substrate 1 on which the aforementioned patterns are formed, performing patterned etching to remove the dielectric layer, the insulating layer 41, and a part of the metal oxide conductive thin film, so that the metal oxide conductive thin film forms an integrated structure 10, and the metal oxide conductive thin film in a region corresponding to the first capacitor electrode is exposed, as shown in FIG. le.
Step 106: forming a capacitor dielectric layer.

Forming the capacitor dielectric layer includes on the basis of the substrate 1 on which the aforementioned patterns are formed, forming a capacitor dielectric layer 33 on the outer side wall and the inner side wall of the exposed metal oxide conductive thin film in the region corresponding to the first capacitor electrode and on the side wall of the insulating layer 41 by an atomic layer deposition process, as shown in FIG. 1f. The film layer is only located on the inner side wall without filling the inner side wall completely.
Step 107: forming a second capacitor electrode.

Forming the second capacitor electrode includes on the basis of the substrate 1 on which the aforementioned patterns are formed, depositing a conductive thin film on the substrate 1, so that the conductive thin film forms a second capacitor electrode 32, and at least a part of the second capacitor electrode 32 surrounds the outer side wall and end face of the first capacitor electrode, with the capacitor dielectric layer 33 interposed between them, as shown in FIG. 1. Herein, the first capacitor electrode and the second capacitor electrode 32 form a capacitor.

In an embodiment of the present disclosure, the first capacitor electrode, the first electrode, the channel, and the second electrode are formed by the same metal oxide conductive material, so that the first capacitor electrode, the first electrode, the channel, and the second electrode are of an integrated structure, which simplifies the production process, reduces the production cost, and is easy to manufacture.

In an embodiment of the present disclosure, in the integrated structure, a region from the first capacitor electrode to the second electrode is a solid structure, so that the outer side wall and the end face of the first capacitor electrode of the solid structure are surrounded by the second capacitor electrode, thereby increasing the relative area between the second capacitor electrode and the first capacitor electrode, and improving the capacity of the capacitor.

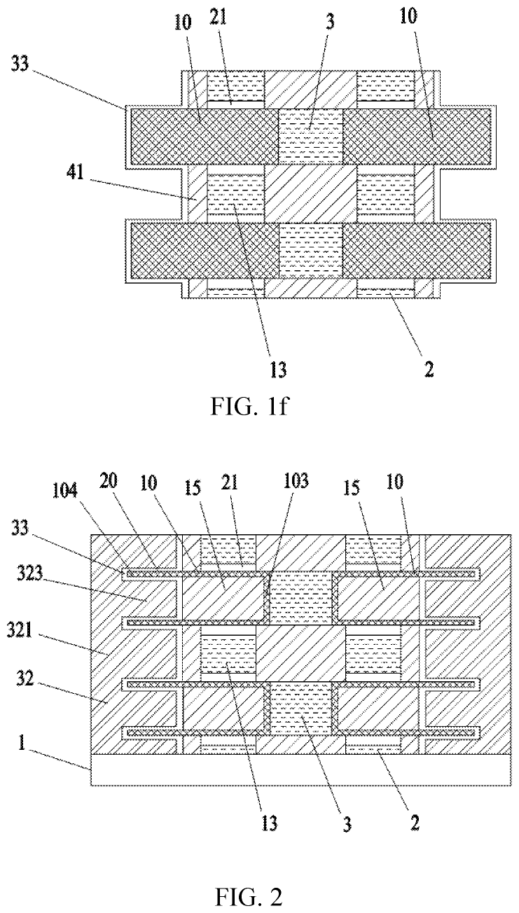

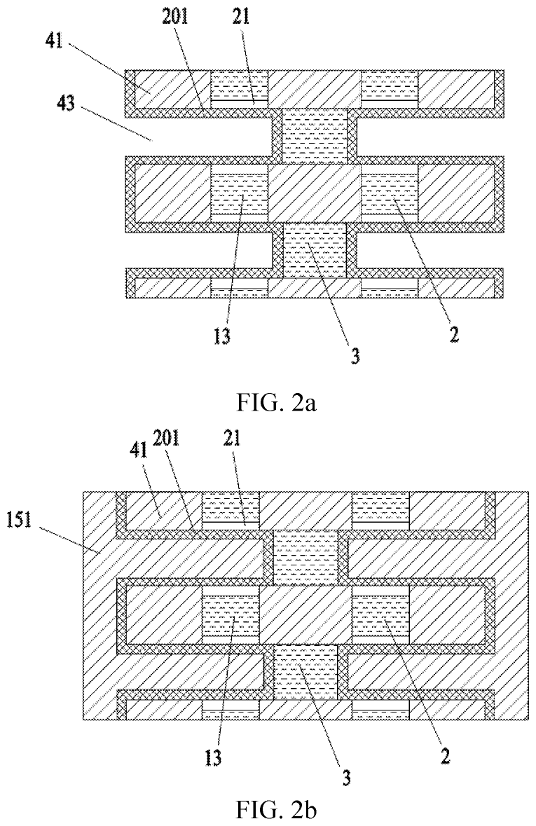

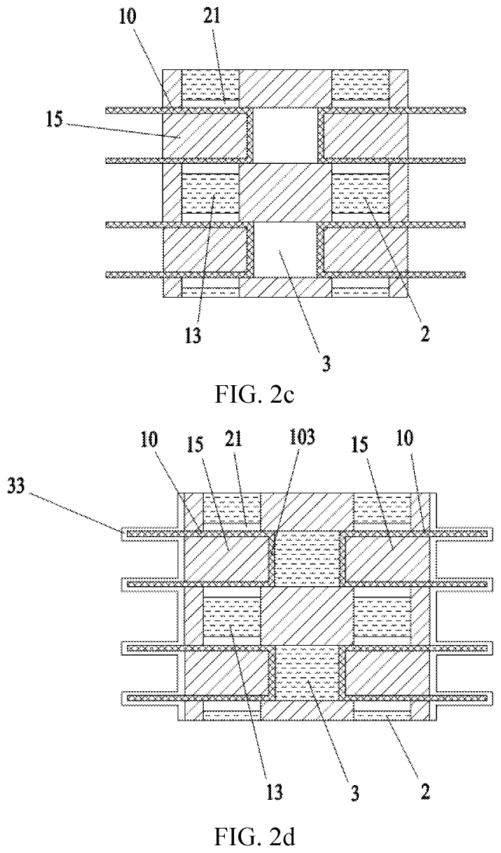

FIG. 2 is a second schematic cross-sectional view of a semiconductor device according to an exemplary embodiment along a direction perpendicular to a substrate. In an exemplary embodiment, as shown in FIG. 2, an embodiment of the present disclosure provides a semiconductor device, and the semiconductor device of the embodiment of the present disclosure is different from the semiconductor device shown in FIG. 1 in that at least a part of regions of the integrated structure 10 is a hollow structure. At least the region where the first capacitor electrode is located is a hollow structure, and one end of the integrated structure 10 close to the capacitor has an opening 104 facing the second capacitor electrode 32. The second capacitor electrode 32 surrounds the outer side wall of the first capacitor electrode and penetrates into the opening 104, and the second capacitor electrode 32 is simultaneously connected to the outer side wall and the inner side wall of the first capacitor electrode through the capacitor dielectric layer 33.

In an embodiment of the present disclosure, at least the region where the first capacitor electrode is located is a hollow structure, and the second capacitor electrode surrounds the outer side wall of the first capacitor electrode and penetrates into the opening, thereby increasing the relative area between the second capacitor electrode and the first capacitor electrode, and improving the capacity of the capacitor.

In an exemplary embodiment, as shown in FIG. 2, in the integrated structure 10, a region corresponding to the channel, the first electrode, and the second electrode is a hollow structure, and the hollow structure extends from the first capacitor electrode toward the bit line 3 to form a cup-shaped structure. Different regions of the side wall of the cup-shaped structure are the first capacitor electrode, the first electrode, and the channel, and the second electrode includes at least a bottom surface 103 of the cup-shaped structure, and the bit line 3 is connected to the bottom surface 103 of the cup-shaped structure.

In an exemplary embodiment, as shown in FIG. 2, each of the memory cells includes an aperture 20 extending in a direction perpendicular to the bit line, the side wall of the aperture 20 is an insulating layer, and the bottom of the aperture 20 exposes the bit line 3 in the corresponding region. A metal oxide conductive layer is deposited on the insulating layer of the side wall of the aperture 20 and on the bit line exposed at the bottom, and the metal oxide conductive layer is an integrated structure 10. Different regions of the metal oxide conductive layer in a direction away from the bit line 3 are the second electrode, the channel, the first electrode, and the first capacitor electrode, respectively.

In an exemplary embodiment, as shown in FIG. 2, the insulating layer of the side wall of the aperture 20 includes different insulating layers. The region of the side wall of the aperture 20 corresponding to the channel is the gate insulating layer 21, and the gate insulating layer is an HK film layer. The region of the side wall of the aperture 20 corresponding to the first capacitor electrode is the capacitor dielectric layer 33, and the capacitor dielectric layer is also an HK film layer. The region of the side wall of the aperture 20 corresponding to the first electrode and the second electrode is a second isolation layer, and the isolation layer is an LK film layer. It can be the above-described silicon oxide film layer.

In an exemplary embodiment, as shown in FIG. 2, the metal oxide conductive layer is in a shape adapted to the shape of the aperture 20 to form a hollow cup-shaped structure, and the hollow cup-shaped structure formed by the metal oxide conductive layer is filled with an insulating filling layer 15, and the insulating filling layer 15 is a solid structure extending in a direction parallel to the substrate. The insulating filling layer 15 extends from the bottom of the aperture 20 to the region of the first electrode and does not extend to the region of the first capacitor electrode.

In an exemplary embodiment, as shown in FIG. 2, the capacitor dielectric layer 33 is deposited on the inner side wall of the aperture 20 that is not filled with the insulating filling layer 15, and the shape of the capacitor dielectric layer 33 is adapted to the shape of the aperture 20 that is not filled with the insulating filling layer 15. The second capacitor electrode 32 is filled in the aperture 20 in which the capacitor dielectric layer 33 is formed. The second capacitor electrode 32 is formed in the region of the outer side wall of the aperture 20 corresponding to the capacitor dielectric layer 33.

In an exemplary embodiment, as shown in FIG. 2, the second capacitor electrode 32 has a plate-like structure extending perpendicular to the substrate, and the first capacitor electrode extends into the plate-like structure and is connected via the capacitor dielectric layer 33, so that the shapes of the first capacitor electrode and the second capacitor electrode are complementary.

In an exemplary embodiment, as shown in FIG. 2, the side wall of the aperture 20 includes four surfaces, and the side wall of the aperture 20 includes an upper surface and a lower surface, and two side surfaces. The upper surface and the lower surface are parallel to the substrate.

In an exemplary embodiment, as shown in FIG. 2, the second capacitor electrode 32 is located at a side of the integrated structure 10 away from the bit line 3, and is insulated from the integrated structure 10. The second capacitor electrode 32 includes a main body structure 321 and a protrusion 323 provided on the main body structure 321, and the protrusion 323 extends along a direction parallel to the substrate 1. The protrusion 323 is located on a side of the main body structure 321 close to the integrated structure 10, and the protrusion 323 is provided in the aperture 20, thereby increasing the relative area between the second capacitor electrode 32 and the first capacitor electrode, and improving the capacity of the capacitor.

In an exemplary embodiment, as shown in FIG. 2, in the direction perpendicular to the substrate 1, the protrusions 323 of the second capacitor electrodes 32 of the capacitors of the same column in different layers are arranged at intervals along the direction perpendicular to the substrate 1.

Technical solutions of the embodiments will be further explained through a manufacturing process of the semiconductor device of the embodiment. A “patterning process” mentioned in the embodiments includes film layer deposition, photoresist coating, mask exposure, development, etching, photoresist stripping, and other treatments, and is a mature manufacturing process in related technologies. A “photolithography process” in the embodiments includes film layer coating, mask exposure, and development, and is a mature manufacturing process in the related technologies. Known processes such as sputtering, evaporation, chemical vapor deposition may be used for the deposition, known coating processes may be used for the coating, and known approaches may be used for etching, which are not specifically limited here. In description of the embodiments, it should be understood that a “thin film” refers to a layer of thin film made of a certain material on a base using a deposition or coating process. If the “thin film” does not need a patterning process or photolithography process during the entire manufacturing process, the “thin film” may also be called a “layer”. If the “thin film” needs a patterning process or photolithography process during the entire manufacturing process, it is called a “thin film” before the patterning process and a “layer” after the patterning process. The “layer” after the patterning process or photolithography process contains at least one “pattern”.

In the present embodiment, each layer includes a plurality of memory cells, but the embodiment of the present disclosure is not limited thereto, and each layer may include one memory cell.

In an exemplary embodiment, the manufacturing process of the semiconductor device may include following steps.
Step 201: forming insulating layers and conductive layers. Step 201 is substantially the same as step 101 described above.
Step 202: forming a gate. Step 202 is substantially the same as step 102 described above.
Step 203: forming a trench body. Step 203 is substantially the same as the step 103 described above.
Step 204: forming a metal oxide conductive thin film.

Forming the metal oxide conductive thin film includes: on the basis of the substrate 1 on which the aforementioned patterns are formed, forming a continuously distributed metal oxide conductive thin film 201 on the side wall and the bottom of the trench body 43 by an atomic layer deposition process, so that different regions of the metal oxide conductive thin film 21 form a first capacitor electrode, a first electrode, a channel, and a second electrode. The second electrode is connected to a bit line at the bottom of the trench body, and the metal oxide conductive thin film 201 in the trench body has a cup-shaped structure, as shown in FIG. 2a.
Step 205: forming a dielectric thin film.

Forming the dielectric thin film includes: on the basis of the substrate 1 on which the aforementioned patterns are formed, filling the trench body with an insulating material 151. The insulating material 151 fills the entire trench body from the bottom of the trench body along the side wall, and the insulating material 151 in the trench body has a solid structure, as shown in FIG. 2b.
Step 206: forming an integrated structure and an insulating filling layer.

Forming the integrated structure and the insulating filling layer includes on the basis of the substrate 1 on which the aforementioned patterns are formed, performing wet selective etching from the cup mouth end of the cup-shaped structure, to remove only the insulating material in the region corresponding to the first capacitor electrode, so that the metal oxide conductive thin film forms the integrated structure 10, the region corresponding to the first capacitor electrode is exposed, and the retained insulating material forms the insulating filling layer 15, as shown in FIG. 2c.
Step 207: forming a capacitor dielectric layer.

Forming the capacitor dielectric layer includes on the basis of the substrate 1 on which the aforementioned patterns are formed, forming the capacitor dielectric layer 33 in the trench body retained in the region corresponding to the first capacitor electrode by an atomic layer deposition process, as shown in FIG. 2d.
Step 208: forming a second capacitor electrode.

Forming the second capacitor electrode includes on the basis of the substrate 1 on which the aforementioned patterns are formed, depositing a conductive thin film on the substrate, so that the second conductive thin film forms a second capacitor electrode 32, and at least a part of the second capacitor electrode 32 surrounds the outer side wall and the inner side wall of the first capacitor electrode, with the capacitor dielectric layer 33 interposed between them, as shown in FIG. 2. Herein, the first capacitor electrode and the second capacitor electrode 32 form a capacitor.

The solution provided by the present embodiment simplifies the process flow, is easy to implement, improves the production efficiency, and has the advantages of easy process realization, low production cost and high yield rate and the like.

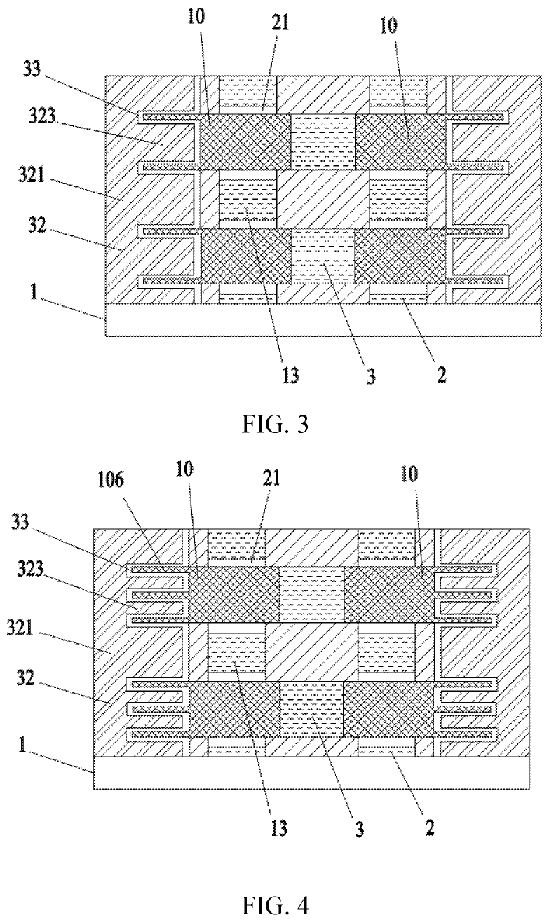

FIG. 3 is a third schematic cross-sectional view of a semiconductor device according to an exemplary embodiment along a direction perpendicular to a substrate. In an exemplary embodiment, as shown in FIG. 3, an embodiment of the present disclosure provides a semiconductor device, and the semiconductor device of the embodiment of the present disclosure is different from the semiconductor device shown in FIG. 2 in that, in the integrated structure, a region where the first capacitor electrode is located is a hollow structure, and regions corresponding to the channel, the first electrode, and the second electrode are all solid structures.

In an exemplary embodiment, as shown in FIG. 3, the second capacitor electrode 32 is located at a side of the integrated structure 10 away from the bit line 3, and is insulated from the integrated structure 10. The second capacitor electrode 32 includes a main body structure 321 and a protrusion 323 provided on the main body structure 321, and the protrusion 323 extends along a direction parallel to the substrate 1. The protrusion 323 is located on a side of the main body structure 321 close to the integrated structure 10, and the protrusion 323 is provided in the hollow structure of the integrated structure 10, thereby increasing the relative area between the second capacitor electrode 32 and the first capacitor electrode and improving the capacity of the capacitor.

FIG. 4 is a fourth schematic cross-sectional view of a semiconductor device according to an exemplary embodiment along a direction perpendicular to a substrate. In an exemplary embodiment, as shown in FIG. 4, an embodiment of the present disclosure provides a semiconductor device. The semiconductor device of the embodiment of the present disclosure is different from the semiconductor device shown in FIG. 3 in that, in the integrated structure, regions corresponding to the channel, the first electrode, and the second electrode are solid structures, and the region where the first capacitor electrode is located includes a plurality of cup-shaped portions 106 stacked in a direction perpendicular to the substrate. The plurality of cup-shaped portions 106 have the same depth.

In an exemplary embodiment, as shown in FIG. 4, the second capacitor electrode 32 includes a main body structure 321 and a plurality of protrusions 323 disposed on the main body structure 321 and stacked in a direction perpendicular to the substrate. The protrusions 323 are disposed in the corresponding cup-shaped portion 106, thereby increasing the relative area between the second capacitor electrode 32 and the first capacitor electrode and improving the capacity of the capacitor.

An embodiment of the present disclosure further provides a manufacturing method for a semiconductor device, and the semiconductor device may be the semiconductor device described in any one of above embodiments.

The manufacturing method for the semiconductor device includes following operations: forming conductive layers and insulating layers disposed alternately and sequentially on a substrate; performing patterned etching to form a plurality of trenches perpendicular to the substrate, the conductive layers respectively forming patterned structures mutually stacked and sequentially circularly distributed, and each layer of the patterned structures including a bit line and a plurality of branches extending in a direction perpendicular to the bit line; filling the trenches with a dielectric layer; performing patterned etching to expose ends of the plurality of branches away from the bit line; performing wet selective etching to remove each branch to form a trench body extending along a direction parallel to the substrate, the trench body exposing the bit line of a corresponding region; forming a continuously distributed metal oxide conductive thin film in the trench body, so that different regions of the metal oxide conductive thin film form a first capacitor electrode, a first electrode, a channel and a second electrode, the second electrode being connected to the exposed bit line; performing patterned etching to expose a region corresponding to the first capacitor electrode; and sequentially forming a capacitor dielectric layer and a second capacitor electrode in the region corresponding to the first capacitor electrode.

In an exemplary embodiment, in the manufacturing method for the semiconductor device, after forming conductive layers and insulating layers disposed alternately and sequentially on a substrate, the method further includes: forming a passage surrounding a portion of side walls of the conductive layers in the insulating layers, the passage exposing the portion of the side walls of the conductive layers; forming a gate insulating layer in the passage; and forming a gate and a word line on the substrate, at least part of the gate being disposed in the passage.

In some embodiments, the manufacturing method for the semiconductor device includes: forming a continuously distributed metal oxide conductive thin film on a side wall and a bottom of the trench body by an atomic layer deposition process, so that different regions of the metal oxide conductive thin film form a first capacitor electrode, a first electrode, a channel and a second electrode, the second electrode being connected to the exposed bit line; filling the trench body with an insulating material to fill the trench body completely; performing wet selective etching to remove the insulating material in the region corresponding to the first capacitor electrode, so that the trench body is retained in the region corresponding to the first capacitor electrode, and the region corresponding to the first capacitor electrode is exposed; retaining an insulating thin film in the region of the trench body corresponding to the first electrode, the second electrode and the channel to form an insulating filling layer; and sequentially forming a capacitor dielectric layer and a second capacitor electrode filled in the retained trench body in the retained trench body in the region corresponding to the first capacitor electrode, both the capacitor dielectric layer and the second capacitor electrode being in a shape of a film layer, or the second capacitor electrode is in a shape of a block, a column, a line, etc., filling the entire trench.

In some embodiments, the manufacturing method for the semiconductor device, after filling the trenches with the dielectric layer, further includes: forming a passage exposing side walls of the conductive layers in the insulating layers, the passage exposing and connecting the side walls of the conductive layers; and sequentially forming, in the passage, gate insulating layers and gates surrounding the side walls of the conductive layers, the gates being connected to form a word line, and memory cells stacked perpendicular to the substrate share one word line.

In some embodiments, the manufacturing method for the semiconductor device, after filling the trenches with the dielectric layer, further includes: forming a through hole extending in a vertical direction between two adjacent memory cells in a same layer, laterally etching within the through hole to expose side walls of conductive layers of stacked memory cells corresponding to the two adjacent memory cells, and sequentially forming a gate insulating layer and a word line within the through hole, the word line being simultaneously connected with the two adjacent memory cells; and disconnecting the shared word line into two word lines extending along a direction perpendicular to the substrate, and forming an isolation layer between the word lines.

An embodiment of the present disclosure further an electronic device, which includes the semiconductor device described in any one of the foregoing embodiments. The electronic device may be a storage device, a smart phone, a computer, a tablet computer, an artificial intelligence device, a wearable device or a mobile power supply, etc. The storage device may include a memory in a computer or the like, which is not limited here.

Although implementations disclosed in the present disclosure are as the above, the described contents are only implementations used for facilitating understanding the present disclosure, and are not intended to limit the present disclosure. Any person skilled in the art to which the present disclosure pertains may make any modification and variation in the form and details of implementations without facing away from the spirit and the scope disclosed in the present disclosure. Nevertheless, the scope of patent protection of the present disclosure shall still be subject to the scope defined by the appended claims.

1. A semiconductor device comprising: a plurality of memory cells stacked in a direction perpendicular to a substrate, and a bit line and a word line; wherein a memory cell of the plurality of memory cells comprises a transistor and a capacitor;
the transistor comprises a channel, a first electrode, a second electrode, and a gate, the second electrode is connected to the bit line, and the first electrode is connected to the capacitor; the gate surrounds the channel and is connected to the channel by a gate insulating layer;
the capacitor comprises a first capacitor electrode, a second capacitor electrode, and a capacitor dielectric layer, wherein the first capacitor electrode is connected to the first electrode; and
the first capacitor electrode, the first electrode, the channel, and the second electrode are of an integrated structure and formed of a same metal oxide conductive material.

2. The semiconductor device according to claim 1, wherein a conductivity of the channel is the same as a conductivity of the first capacitor electrode, the first electrode, and the second electrode.

3. The semiconductor device according to claim 1, wherein the first capacitor electrode, the first electrode, the channel, and the second electrode are respectively different regions of the metal oxide conductive material extending in a direction parallel to the substrate.

4. The semiconductor device according to claim 3, wherein the integrated structure has a linear shape extending in the direction parallel to the substrate and perpendicular to the bit line, and an end of the integrated structure is connected to the bit line, wherein the bit line is made of metal, alloy, or metal nitride; and
wherein in the integrated structure, a region from the first capacitor electrode to the second electrode is a solid structure, and an outer side wall and an end face of the first capacitor electrode of the solid structure are surrounded by the second capacitor electrode.

5. (canceled)

6. The semiconductor device according to claim 1, wherein at least a part of regions of the integrated structure is a hollow structure; and
wherein at least a region where the first capacitor electrode is located is a hollow structure, and an end of the integrated structure close to the capacitor has an opening facing the second capacitor electrode; the second capacitor electrode surrounds an outer side wall of the first capacitor electrode and penetrates into the opening, and the second capacitor electrode is connected to the outer side wall and an inner side wall of the first capacitor electrode through the capacitor dielectric layer.

7. The semiconductor device according to claim 6, wherein in the integrated structure, regions corresponding to the channel, the first electrode, and the second electrode are all solid structures; or
wherein in the integrated structure, a region corresponding to the channel, the first electrode, and the second electrode is a hollow structure, the hollow structure extends from the first capacitor electrode toward the bit line to form a cup-shaped structure, the second electrode comprises at least a bottom surface of the cup-shaped structure, and the bit line is connected to the bottom surface of the cup-shaped structure.

8. (canceled)

9. The semiconductor device according to claim 1, wherein each of the memory cells comprises an aperture extending in a direction perpendicular to the bit line, a side wall of the aperture is an insulating layer, and a bottom of the aperture exposes the bit line of a corresponding region; and
a metal oxide conductive layer is deposited on the insulating layer of the side wall of the aperture and on the bit line exposed at the bottom, and different regions of the metal oxide conductive layer in a direction away from the bit line are respectively the second electrode, the channel, the first electrode and the first capacitor electrode.

10. The semiconductor device according to claim 9, wherein the insulating layer of the side wall of the aperture comprises different insulating layers, wherein a region of the side wall of the aperture corresponding to the channel is the gate insulating layer, a region of the side wall of the aperture corresponding to the first capacitor electrode is the capacitor dielectric layer, and a region of the side wall of the aperture corresponding to the first electrode and the second electrode is an isolation layer.

11. The semiconductor device according to claim 9, wherein the metal oxide conductive layer is in a shape adapted to a shape of the aperture and forms a hollow cup-shaped structure, and the hollow cup-shaped structure formed by the metal oxide conductive layer is filled with an insulating filling layer.

12. The semiconductor device according to claim 11, wherein the insulating filling layer extends from the bottom of the aperture to a region of the first electrode and does not extend to a region of the first capacitor electrode;
the capacitor dielectric layer is deposited on an inner side wall of the aperture not filled with the insulating filling layer, and the capacitor dielectric layer has a shape adapted to the shape of the aperture not filled with the insulating filling layer; and
the second capacitor electrode is filled in the aperture in which the capacitor dielectric layer is formed; the second capacitor electrode is formed in a region of an outer side wall of the aperture corresponding to the capacitor dielectric layer.

13. The semiconductor device according to claim 12, wherein the second capacitor electrode has a plate-like structure extending perpendicular to the substrate, and the first capacitor electrode extends into the plate-like structure and is connected by the capacitor dielectric layer such that shapes of the first capacitor electrode and the second capacitor electrode are complementary.

14. The semiconductor device according to claim 9, wherein the side wall of the aperture comprises four surfaces, the side wall of the aperture comprises an upper surface and a lower surface, and two side surfaces, wherein the upper surface and the lower surface are parallel to the substrate.

15. The semiconductor device according to claim 1, wherein the metal oxide conductive material is indium tin oxide or indium zinc oxide; and
wherein a contact between the bit line and the channel or the second electrode is an ohmic contact.

16. (canceled)

17. The semiconductor device according to claim 1, wherein two adjacent memory cells in a same layer share one bit line, and the two adjacent memory cells are mirror-symmetrically distributed.

18. The semiconductor device according to claim 1, wherein the word line extends in the direction perpendicular to the substrate and the bit line extends in a direction parallel to the substrate.

19. A manufacturing method for a semiconductor device, comprising:
forming conductive layers and insulating layers disposed alternately and sequentially on a substrate;
performing patterned etching to form a plurality of trenches perpendicular to the substrate, wherein the conductive layers respectively form patterned structures mutually stacked and sequentially circularly distributed, and each layer of the patterned structures comprises a bit line and a plurality of branches extending in a direction perpendicular to the bit line;
filling the trenches with a dielectric layer;
performing patterned etching to expose ends of the plurality of branches away from the bit line;
performing wet selective etching to remove each of the branches wrapped by the dielectric layer and the insulating layers to form a trench body extending along a direction parallel to the substrate, wherein the trench body exposes the bit line of a corresponding region;
forming a continuously distributed metal oxide conductive thin film in the trench body, so that different regions of the metal oxide conductive thin film form a first capacitor electrode, a first electrode, a channel and a second electrode; wherein the second electrode is connected to the bit line exposed;
performing patterned etching to remove the dielectric layer and the insulating layers to expose the metal oxide conductive thin film in a region corresponding to the first capacitor electrode; and
sequentially forming a capacitor dielectric layer and a second capacitor electrode on an outer side wall and an inner side wall of the metal oxide conductive thin film in the region corresponding to the first capacitor electrode.

20. The manufacturing method for the semiconductor device according to claim 19, comprising:
forming a continuously distributed metal oxide conductive thin film on a side wall and a bottom of the trench body by an atomic layer deposition process, wherein different regions of the metal oxide conductive thin film form the first capacitor electrode, the first electrode, the channel and the second electrode; the second electrode is connected to the bit line at the bottom of the trench body;
filling the trench body with an insulating material, wherein the insulating material fills an entire trench body from the bottom of the trench body along the side wall;
performing wet selective etching to remove only the insulating material in the region corresponding to the first capacitor electrode; and
sequentially forming, in a retained trench body in the region corresponding to the first capacitor electrode, the capacitor dielectric layer and the second capacitor electrode filled in the retained trench body.

21. The manufacturing method for the semiconductor device according to claim 19, wherein, after filling the trenches with the dielectric layer, the manufacturing method further comprises:
forming a passage exposing side walls of the conductive layers in the insulating layers, wherein the passage exposes and connects the side walls of the conductive layers; and
sequentially forming, in the passage, gate insulating layers and gates surrounding the side walls of the conductive layers, wherein the gates are connected to form a word line, and memory cells stacked perpendicular to the substrate share one word line.

22. The manufacturing method for the semiconductor device according to claim 21, wherein, after filling the trenches with the dielectric layer, the manufacturing method further comprises:
forming a through hole extending in a vertical direction between two adjacent memory cells in a same layer, laterally etching within the through hole to expose the side walls of the conductive layers of the stacked memory cells corresponding to the two adjacent memory cells, and sequentially forming a gate insulating layer and a word line within the through hole, wherein the word line is simultaneously connected with the two adjacent memory cells; and
disconnecting the word line shared into two mutually independent word lines extending along a direction perpendicular to the substrate, and forming an isolation layer between the mutually independent word lines.

23. An electronic device, comprising the semiconductor device according to claim 1.
